(19) United States
(12) Patent Application Publication
(10) Pub. No.: US 2022/0113092 A1
(43) Pub. Date: Apr. 14, 2022

(54) HEAT PIPE WITH FIRST HEAT SOURCE ON FIRST SIDE AND SECOND HEAT SOURCE ON OPPOSITE SECOND SIDE

(71) Applicant: Intel Corporation, Santa Clara, CA (US)

(72) Inventors: Jeff Ku, Taipei (TW); Baomin Liu, Austin, TX (US); Cora Nien, Changhua County (TW)

(73) Assignee: Intel Corporation, Santa Clara, CA (US)

(21) Appl. No.: 17/560,070

(22) Filed: Dec. 22, 2021

(51) Int. Cl. F28D 15/02; H05K 7/20; F28D 15/04

(52) U.S. Cl. CPC F28D 15/0233; F28D 15/0275; F28D 15/04; H05K 7/20336

(57) ABSTRACT

Particular embodiments described herein provide for an electronic device that can be configured to include a first support structure that includes a first heat source, a second support structure that includes a second heat source, and a heat pipe that has a first side and an opposite second side, where the first heat source is coupled to the first side of the heat pipe and the second heat source is coupled to the second side of the heat pipe. In some examples, the heat pipe can be a vapor chamber.

### TECHNICAL FIELD

This disclosure relates in general to the field of computing and/or device cooling, and more particularly, to a heat pipe with a first heat source on a first side and a second heat source on an opposite second side.

### BACKGROUND

Emerging trends in electronic devices are changing the expected performance and form factor of devices as devices and systems are expected to increase performance and function while having a relatively thin profile. However, the increase in performance and/or function causes an increase in the thermal challenges of the devices and systems. Insufficient cooling can cause a reduction in device performance, a reduction in the lifetime of a device, and delays in data throughput.

### BRIEF DESCRIPTION OF THE DRAWINGS

To provide a more complete understanding of the present disclosure and features and advantages thereof, reference is made to the following description, taken in conjunction with the accompanying figures, wherein like reference numerals represent like parts, in which:

FIGS. 1A and 1B are a simplified block diagram of a system to help enable a heat pipe with a first heat source on a first side and a second heat source on an opposite second side, in accordance with an embodiment of the present disclosure;

FIG. 2 is a simplified block diagram of a perspective view of a portion of a system to help enable a heat pipe with a first heat source on a first side and a second heat source on an opposite second side, in accordance with an embodiment of the present disclosure;

FIG. 3 is a simplified block diagram of a perspective view of a portion of a system to help enable a heat pipe with a first heat source on a first side and a second heat source on an opposite second side, in accordance with an embodiment of the present disclosure;

FIG. 4 is a simplified block diagram of a perspective view of a portion of a system to help enable a heat pipe with a first heat source on a first side and a second heat source on an opposite second side, in accordance with an embodiment of the present disclosure;

FIGS. 5 is a simplified block diagram side view of a portion of a system to help enable a heat pipe with a first heat source on a first side and a second heat source on an opposite second side, in accordance with an embodiment of the present disclosure;

FIG. 6 is a simplified block diagram side view of a portion of a system to help enable a heat pipe with a first heat source on a first side and a second heat source on an opposite second side, in accordance with an embodiment of the present disclosure;

FIG. 7 is a simplified block diagram side view of a portion of a system to help enable a heat pipe with a first heat source on a first side and a second heat source on an opposite second side, in accordance with an embodiment of the present disclosure;

FIG. 8 is a simplified block diagram side view of a portion of a system to help enable a heat pipe with a first heat source on a first side and a second heat source on an opposite second side, in accordance with an embodiment of the present disclosure;

FIG. 9 is a simplified block diagram side view of a portion of a system to help enable a heat pipe with a first heat source on a first side and a second heat source on an opposite second side, in accordance with an embodiment of the present disclosure

FIG. 10 is a simplified block diagram side view of a portion of a system to help enable a heat pipe with a first heat source on a first side and a second heat source on an opposite second side, in accordance with an embodiment of the present disclosure;

FIG. 11 is a simplified block diagram side view of a portion of a system to help enable a heat pipe with a first heat source on a first side and a second heat source on an opposite second side, in accordance with an embodiment of the present disclosure;

FIGS. 12A and 12B are simplified block diagram top views of a portion of a system to help enable a heat pipe with a first heat source on a first side and a second heat source on an opposite second side, in accordance with an embodiment of the present disclosure;

FIGS. 13A and 13B are a simplified block diagram perspective views of a portion of a system to help enable a heat pipe with a first heat source on a first side and a second heat source on an opposite second side, in accordance with an embodiment of the present disclosure; and

FIG. 14 is a simplified block diagram of an electronic device that includes a heat pipe with a first heat source on a first side and a second heat source on an opposite second side, in accordance with an embodiment of the present disclosure.

The FIGURES of the drawings are not necessarily drawn to scale, as their dimensions can be varied considerably without departing from the scope of the present disclosure.

### DETAILED DESCRIPTION

### Example Embodiments

The following detailed description sets forth examples of apparatuses, methods, and systems relating to enabling a heat pipe with a first heat source on a first side and a second heat source on an opposite second side. Features such as structure(s), function(s), and/or characteristic(s), for example, are described with reference to one embodiment as a matter of convenience; various embodiments may be implemented with any suitable one or more of the described features.

In an example, an electronic device can include a heat pipe that includes a first side and an opposite second side. The first side can be coupled to a first heat source on a first support structure (e.g., a substrate or printed circuit board (PCB)) and the second side can be coupled to a second heat source on a second support structure (e.g., a second substrate or second PCB). More specifically, the first heat source can be a computer processing unit (CPU) on a CPU substrate or CPU PCB and the second heat source can be a graphics processing unit (GPU) on a GPU substrate or GPU PCB (e.g., a modular graphic card). In some examples, the heat pipe can be a vapor chamber. In other examples, the heat pipe may not be a heat pipe or vapor chamber but some other heat sink (e.g., a cold plate) that helps to remove heat from the heat sources and can be comprised of aluminum, copper, or some other thermally conductive material.

In an illustrative example, in instead of the heat pipe being on top of the first heat source and the second heat source as with current devices that include a heat pipe, the heat pipe can be located over the first heat source and under the second heat source (e.g., the first heat source is under the heat pipe and the second heat source is over the heat pipe) or vice versa. The electronic device can also include one or more heat exchangers. The one or more heat exchangers can be located on one side of the heat pipe or on both sides of the heat pipe. The heat exchangers can include one or more fins and an air mover (e.g., blower or fan) can direct air over the fins to help dissipate heat from the first heat source and the second heat source that has been collected by the heat pipe and transferred to the fins.

In the following description, various aspects of the illustrative implementations will be described using terms commonly employed by those skilled in the art to convey the substance of their work to others skilled in the art. However, it will be apparent to those skilled in the art that the embodiments disclosed herein may be practiced with only some of the described aspects. For purposes of explanation, specific numbers, materials, and configurations are set forth in order to provide a thorough understanding of the illustrative implementations. However, it will be apparent to one skilled in the art that the embodiments disclosed herein may be practiced without the specific details. In other instances, well-known features are omitted or simplified in order not to obscure the illustrative implementations.

The terms “over,” “under,” “below,” “between,” and “on” as used herein refer to a relative position of one layer or component with respect to other layers or components. For example, one layer or component disposed over or under another layer or component may be directly in contact with the other layer or component or may have one or more intervening layers or components. Moreover, one layer or component disposed between two layers or components may be directly in contact with the two layers or components or may have one or more intervening layers or components. In contrast, a first layer or first component “directly on” a second layer or second component is in direct contact with that second layer or second component. Similarly, unless explicitly stated otherwise, one feature disposed between two features may be in direct contact with the adjacent features or may have one or more intervening layers.

In the following detailed description, reference is made to the accompanying drawings that form a part hereof wherein like numerals designate like parts throughout, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). Reference to “one embodiment” or “an embodiment” in the present disclosure means that a particular feature, structure, or characteristic described in connection with the embodiment is included in at least one embodiment. The appearances of the phrase “in one embodiment” or “in an embodiment” are not necessarily all referring to the same embodiment. The appearances of the phrase “for example,” “in an example,” or “in some examples” are not necessarily all referring to the same example.

Furthermore, the term “connected” may be used to describe a direct connection between the things that are connected, without any intermediary devices, while the term “coupled” may be used to describe either a direct connection between the things that are connected, or an indirect connection through one or more intermediary devices. The terms “substantially,” “close,” “approximately,” “near,” and “about,” generally refer to being within +/−20% of a target value based on the context of a particular value as described herein or as known in the art. Similarly, terms indicating orientation of various elements (e.g., “coplanar,” “perpendicular,” “orthogonal,” “parallel,” or any other angle between the elements), generally refer to being within +/−5-20% of a target value based on the context of a particular value as described herein or as known in the art.

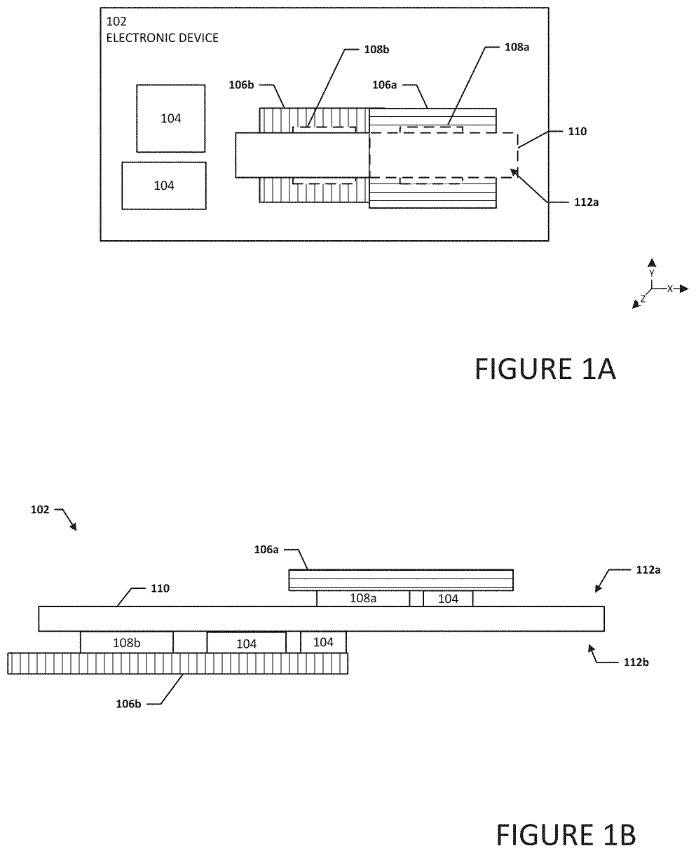

Turning to FIG. 1A, FIG. 1A is a simplified block diagram of an electronic device 102 configured with a heat pipe with a first heat source on a first side and a second heat source on an opposite second side, in accordance with an embodiment of the present disclosure. In an example, the electronic device 102 can include one or more electronic components 104, a first support structure 106a, a second support structure 106b, and a heat pipe 110. The first support structure 106a can include a first heat source 108a. The second support structure 106b can include a second heat source 108b. In some examples, the heat pipe 110 is a vapor chamber. Generally, a vapor chamber is a planer heat pipe where the thermal conductivity is in a two-dimensional heat transfer direction while the thermal conductivity in a heat pipe is along a single axis.

Each of the electronic components 104 can be a device or group of devices available to assist in the operation or function of the electronic device 102. The first support structure 104a and the second support structure 104b can each be a substrate and more particularly, a PCB. Each of the first heat source 108a and the second heat source 108b may be a heat generating device (e.g., processor, logic unit, field programmable gate array (FPGA), chip set, integrated circuit (IC), a graphics processor, graphics card, battery, memory, or some other type of heat generating device). More specifically, the first heat source 108a can be a CPU on a CPU substrate or CPU PCB and the second heat source 108b can be a GPU on a GPU substrate or GPU PCB.

The heat pipe 110 can include a first side 112a and a second side 112b (referenced in FIG. 1B). The first side 112a of the heat pipe 110 is opposite the second side 112b of the heat pipe 110. The first support structure 104a, and more particularly the first heat source 108a can be over the first side 112a of the heat pipe 110. The second support structure 104b, and more particularly the second heat source 108b can be under the second side 112b of the heat pipe 110. Note that the terms “over” and “under” are relative terms depending on the orientation of the electronic device and the heat pipe. More specifically, in a different orientation, the first support structure 104a, and more particularly the first heat source 108a can be under the first side 112a of the heat pipe 110 and the second support structure 104b, and more particularly the second heat source 108b can be over the second side 112b of the heat pipe 110.

Turning to FIG. 1B, FIG. 1B is a simplified block diagram of a portion of the electronic device 102 configured with a heat pipe with a first heat source on a first side and a second heat source on an opposite second side. In an example, the electronic device 102 can include the one or more electronic components 104, the first support structure 106a, the second support structure 106b, and the heat pipe 110. The first support structure 106a can include the first heat source 108a and one or more electronic components 104. The second support structure 106b can included the second heat source 108b and one or more electronic components 104. The heat pipe 110 can include the first side 112a and the second side 112b. The first support structure 104a, and more particularly the first heat source 108a can be over the first side 112a of the heat pipe 110. The second support structure 104b, and more particularly the second heat source 108b can be under the second side 112b of the heat pipe 110.

The heat pipe 110 is filled with a working fluid. Heat from the first heat source 108a and the second heat source 108b causes a liquid portion of the working fluid to vaporize into vapor. The vapor travels away from the first heat source 108a and the second heat source 108b and once cooled, the vapor condenses back into the liquid, thus completing the vapor-liquid flow loop. The vapor-liquid flow loop allows the heat pipe 110 to combine the principles of thermal conductivity and phase transition to transfer heat between two interfaces such as a heat source (e.g., the first heat source 108a) and a cold or cool interface (e.g., a cooler environment around the heat source, an air mover or a thin fin array, a cold plate, etc.).

Some current electronic devices have a CPU on a first board and a GPU on a second board. The GPU on the second board can be a modular GPU that allow OEMs and users to swap the GPU to achieve a desired configuration. Current electronic devices that include a CPU on a first board and a GPU on a second board use only one side of a single heat pipe or multiple heat pipes to reach and cool the CPU and GPU. The main problem with such a design is that, due to the Z-height differences of the CPU board and the GPU board, the system Z-height can be relatively thick as compared to the Z-height of an electronic device with the CPU and GPU on the same board. In addition, the heat pipes are mostly independent heat pipes due to the Z-height differences of the CPU board and the GPU board packages. Also, the CPU and GPU are facing the same direction. Because the CPU and GPU face the same direction, the air gaps above and the under the packages are not balanced, which makes either the top portion or the bottom portion of the chassis hot. In addition, because the CPU and GPU face the same direction, they dissipate the heat to the same surface of the chassis and this can create unwanted thermal challenges for the system.

In the electronic device 102, the heat pipe 110 can be bi-oriented and use both the top of the heat pipe 110 and the bottom side of the heat pipe 110 to help cool the first heat source 108a (e.g., a CPU) and the second heat source 108b (e.g., a GPU). In some examples, depending on design choice, design constraints, the thermal load, etc. multiple blowers or fans and fin stacks can be coupled to the heat pipe 110. The heat pipe 110 can be one or more heat pipes, a vapor chamber, cold plate, or some other mechanism, component, and/or material to help transfer heat away from the first heat source 108a and the second heat source 108b.

As used herein, the term “when” may be used to indicate the temporal nature of an event. For example, the phrase “event ‘A’ occurs when event ‘B’ occurs” is to be interpreted to mean that event A may occur before, during, or after the occurrence of event B, but is nonetheless associated with the occurrence of event B. For example, event A occurs when event B occurs if event A occurs in response to the occurrence of event B or in response to a signal indicating that event B has occurred, is occurring, or will occur. Reference to “one embodiment” or “an embodiment” in the present disclosure means that a particular feature, structure, or characteristic described in connection with the embodiment is included in at least one embodiment. The appearances of the phrase “in one embodiment” or “in an embodiment” are not necessarily all referring to the same embodiment.

It is to be understood that other embodiments may be utilized and structural changes may be made without departing from the scope of the present disclosure. Substantial flexibility is provided in that any suitable arrangements and configuration may be provided without departing from the teachings of the present disclosure.

For purposes of illustrating certain example techniques, the following foundational information may be viewed as a basis from which the present disclosure may be properly explained. End users have more media and communications choices than ever before. A number of prominent technological trends are currently afoot (e.g., more computing elements, more online video services, more Internet traffic, more complex processing, etc.), and these trends are changing the expected performance and form factor of devices as devices and systems are expected to increase performance and function while having a relatively thin profile. However, the increase in performance and/or function causes an increase in the thermal challenges of the devices and systems. For example, in some devices, it can be difficult to cool a particular heat source. One way to cool a heat source is to use a heat pipe or vapor chamber.

Heat pipes and vapor chambers are heat-transfer devices that combine the principles of both thermal conductivity and phase transition to transfer heat between two interfaces (e.g., a heat source and a cold or cool interface such as a heatsink). At the hot interface of a heat pipe or vapor chamber (e.g., the portion of the heat pipe or vapor chamber near the heat source), a liquid in contact with a thermally conductive solid surface near the heat source turns into a vapor by absorbing heat from the heat source. The vapor then travels along the heat pipe or through the vapor chamber to the cold or cool interface and condenses back into a liquid, releasing the collected heat. The liquid then returns to the hot interface through either capillary action, centrifugal force, or gravity and the cycle repeats.

A typical heat pipe or vapor chamber consists of a sealed pipe or tube made of a material that is compatible with a working fluid (e.g., copper for water heat pipes or aluminum for ammonia heat pipes). During construction of the heat pipe or vapor chamber, a vacuum pump is typically used to remove the air from an empty heat pipe or vapor chamber. The heat pipe or vapor chamber is partially filled with the working fluid and then sealed. The working fluid mass is chosen such that the heat pipe or vapor chamber contains both vapor and liquid over a desired operating temperature range. Below the operating temperature, the liquid is cold and cannot vaporize into a gas. Above the operating temperature, all the liquid has turned to gas, and the environmental temperature is too high for any of the gas to condense. Thermal conduction is still possible through the walls of the heat pipe or vapor chamber but at a greatly reduced rate of thermal transfer.

Working fluids are chosen according to the temperatures at which the heat pipe or vapor chamber will operate. For example, at extremely low temperature applications, (e.g., about 2-4 K) liquid helium may be used as the working fluid and for extremely high temperatures, mercury (e.g., about 523-923 K), sodium (e.g., about 873-1473 K), or indium (e.g., about 2000-3000 K) may be used as the working fluid. The vast majority of heat pipes or vapor chambers for room temperature applications use water (e.g., about 298-573 K), ammonia (e.g., about 213-373 K), or alcohol (e.g., methanol (e.g., about 283-403 K) or ethanol (e.g., about 273-403 K)) as the fluid. Copper/water heat pipes or vapor chambers have a copper envelope, use water as the working fluid and typically operate in the temperature range of about twenty degrees Celsius (20° C.) to about one-hundred and fifty degrees Celsius (150° C.). Water heat pipes or vapor chamber are sometimes filled by partially filling the heat pipe or vapor chamber with water, heating until the water boils and displaces the air, and then sealing the heat pipe or vapor chamber while hot.

Heat pipes and vapor chambers are ubiquitous in current mobile thermal solutions however, current heat pipes, vapor chambers, and heat sinks use only one side to reach and cool components. For systems that have a CPU board and a separate GPU board, two or more vapor chambers are sometimes used due to the physical separation of the CPU board and the GPU board. Using two vapor champers increases the cost significantly and limits the design of such systems. Also, the thermal load of the CPU and the GPU cannot be shared among the two vapor chamber heat sinks as they are not thermally connected. In addition, use of multiple vapor chambers can result in a high system stack-up and thicker chassis that increases the overall system Z-height. Some systems keep the vapor chamber dimensions the same for both the CPU side and the GPU side to share the same tooling and save cost, keep the fin stacks and fans the same for both sides to minimize the part variations to low the cost, and minimize the gap between the CPU board and the GPU board for smaller system stack-up and thinner chassis. However, in addition to the high cost with multiple vapor chambers, the vapor chambers are not able to share the CPU and the GPU thermal load among the two vapor chambers and as a result are typically less efficient than if a single vapor chamber was used. What is needed is a system to enable a heat pipe with a first heat source on a first side and a second heat source on an opposite second side.

A system to enable a heat pipe with a first heat source on a first side and a second heat source on an opposite second side, as outlined in FIG. 1, can resolve these issues (and others). In an example, a heat pipe (e.g., the heat pipe 110) can be configured to use a first side of the heat pipe to cool a first heat source and a second opposite side of the heat pipe to cool a second heat source. In an example, both top and bottom sides of a heat pipe can be used to reach and cool multiple components on different PCBs. Depending on the thermal load, multiple blowers or fans and fin stacks can be attached to the heat pipe. In a specific example, both sides of a heat pipe can be configured to reach and cool CPU and GPU components on different PCBs, so that the number of heat pipes can be reduced from two to one. As result, the cost can be lower, the system stack-up and the chassis can be reduced.

A heat pipe with both sides used for cooling on can help to reduce the number of heat pipes required for the systems with critical components to cool on multiple PCBs, like a CPU mother board and a GPU card. It can also help to reduce the cost and system stack-up and make the chassis thinner as compared to systems that include multiple heat pipes and vapor chambers. It can leverage the GPU cooling capability of the heat pipe for use to cool the CPU for more performance when the GPU is idle or vice versa, and thus can be more efficient than a system that includes a heat pipe for the CPU and a separate heat pipe the GPU.

In an example, a blower can be used to provide the airflow if the heat pipe size is limited, especially if the heat pipe is a vapor chamber. For example, the heat pipe can include two fin stacks coupled to the top and bottom sides of the heat pipe to dissipate more heat from the first heat source and the second heat source. Also, two blowers can be used, one on the top and one on the bottom, to provide more airflow. In another example, one or more blowers can be above the heat pipe and stay within the same footprint. If the heat pipe is a vapor chamber, this example may require the vapor chamber to extend towards the blower but can help to reduce the overall footprint of the system layout. In yet another example, two axial fans can be located on the two ends of the chassis and drive the airflow through the system and fin stacks by a push-pull mechanism. Other combinations are possible for various PCB layouts, system configurations, actual thermal load, design choice, and/or design constraints.

By allowing the first heat source to be on a first side of the heat pipe and the second heat source to be on a second side of the heat pipe, the first heat source and the second heat source transfer heat to different sides of the chassis. More specifically, if the first heat source is a CPU package and the second heat source is a GPU package, the CPU package and the GPU package face opposite directions to transfer the heat to different chassis surfaces and help keep the skin temperature of the electronic device balanced and lower than some current designs. One or several trans-board heat pipes can be coupled to the CPU package and the GPU package with bending radius and steps or one or more bends that comply with the heat pipe manufacturing requirements. The heat exchangers on the ends of the heat pipes in front of the fan outlets can be used for active heat dissipation.

In an example implementation, the electronic device 102, is meant to encompass a computer, a personal digital assistant (PDA), a laptop or electronic notebook, a cellular telephone, an iPhone, a tablet, an IP phone, network elements, network appliances, servers, routers, switches, gateways, bridges, load balancers, processors, modules, or any other device, component, element, or object that includes a first heat source on a first support structure and a second heat source on a second structure, where the first heat source and the second heat source can be orientated to face each other. The electronic device 102 may include any suitable hardware, software, components, modules, or objects that facilitate the operations thereof, as well as suitable interfaces for receiving, transmitting, and/or otherwise communicating data or information in a network environment. This may be inclusive of appropriate algorithms and communication protocols that allow for the effective exchange of data or information. The electronic device 102 may include virtual elements.

In regards to the internal structure, the electronic device 102 can include memory elements for storing information to be used in operations. The electronic device 102 may keep information in any suitable memory element (e.g., random access memory (RAM), read-only memory (ROM), erasable programmable ROM (EPROM), electrically erasable programmable ROM (EEPROM), application specific integrated circuit (ASIC), etc.), software, hardware, firmware, or in any other suitable component, device, element, or object where appropriate and based on particular needs. Any of the memory items discussed herein should be construed as being encompassed within the broad term ‘memory element.’ Moreover, the information being used, tracked, sent, or received could be provided in any database, register, queue, table, cache, control list, or other storage structure, all of which can be referenced at any suitable timeframe. Any such storage options may also be included within the broad term ‘memory element’ as used herein.

In certain example implementations, functions may be implemented by logic encoded in one or more tangible media (e.g., embedded logic provided in an ASIC, digital signal processor (DSP) instructions, software (potentially inclusive of object code and source code) to be executed by a processor, or other similar machine, etc.), which may be inclusive of non-transitory computer-readable media. In some of these instances, memory elements can store data used for operations described herein. This includes the memory elements being able to store software, logic, code, or processor instructions that are executed to carry out activities or operations.

Additionally, the first heat source 108a and second heat source 108b may each be or include one or more processors that can execute software or an algorithm. In one example, the processors can transform an element or an article (e.g., data) from one state or thing to another state or thing. In another example, activities may be implemented with fixed logic or programmable logic (e.g., software/computer instructions executed by a processor) and the heat elements identified herein could be some type of a programmable processor, programmable digital logic (e.g., a field programmable gate array (FPGA), an erasable programmable read-only memory (EPROM), an electrically erasable programmable read-only memory (EEPROM)) or an ASIC that includes digital logic, software, code, electronic instructions, or any suitable combination thereof. Any of the potential processing elements, modules, and machines described herein should be construed as being encompassed within the broad term ‘processor.’

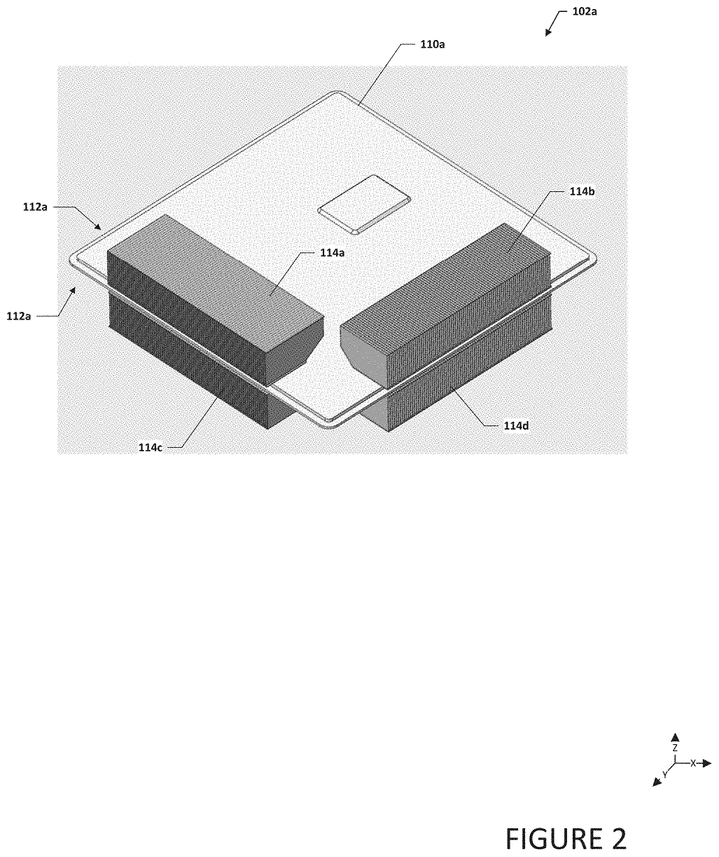

Turning to FIG. 2, FIG. 2 is a simplified block diagram of a portion of an electronic device 102a, in accordance with an embodiment of the present disclosure. In an example, the electronic device 102a can include a heat pipe 110a and one or more heat exchangers 114. The heat pipe 110a can include the first side 112a and the second side 112b. One or more of the heat exchangers 114 can be coupled to the first side 112a of the heat pipe 110a and one or more of the heat exchangers 114 can be coupled to the second side 112b of the heat pipe 110a. In some examples, one or more of the heat exchangers 114 are coupled to only the first side 112a of the heat pipe 110a or only to the second side 112b of the heat pipe 110a. In some examples, the heat pipe 110a is a vapor chamber without any heat exchangers 114.

In an example, as illustrated in FIG. 2, the heat pipe 110a is a vapor chamber or planer heat pipe and the heat exchangers 114 may be fins. For example, as illustrated in FIG. 2, the heat pipe 110a includes four heat exchangers 114a-114d with two heat exchangers 114a and 114b on the first side 112a of the heat pipe 110a and two heat exchangers 114c and 114d on the second side 112b on the heat pipe 110a. The heat exchangers 114a and 114b can be relatively perpendicular to each other and the heat exchangers 114c and 114d can be relatively perpendicular to each other. Note that the number and configuration of the heat exchangers 114 depends on design choice and design constraints and a different number and/or orientation of the heat exchangers 114 may be used then what is illustrated in FIG. 2.

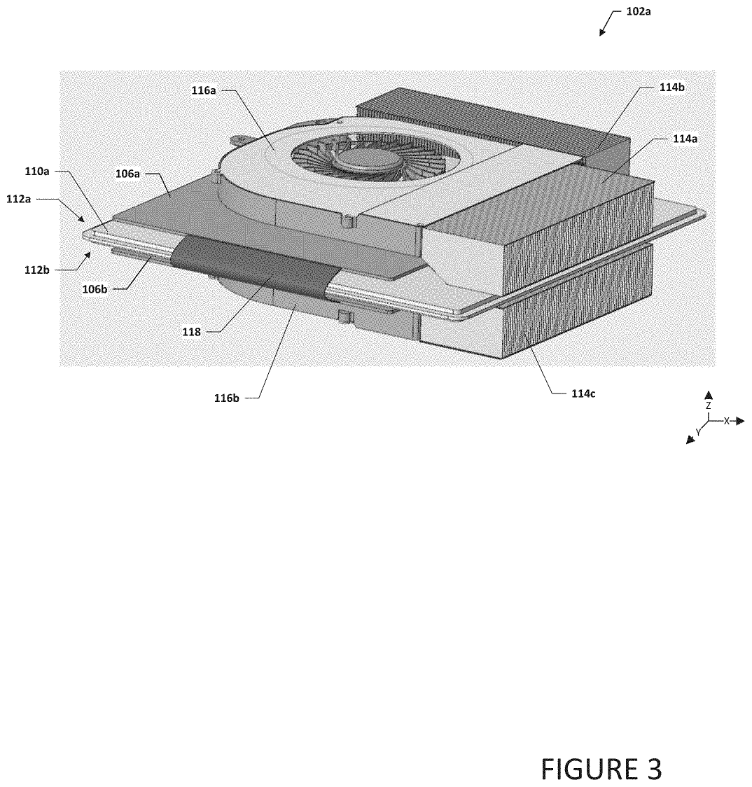

Turning to FIG. 3, FIG. 3 is a simplified block diagram of a portion of the electronic device 102a, in accordance with an embodiment of the present disclosure. FIG. 3 illustrated a top perspective view of the illustrated portion of the electronic device 102a. In an example, the electronic device 102a can include the first support structure 106a, the second support structure 106b, the heat pipe 110a, the heat exchangers 114a-114d (the heat exchanger 114d is not shown), a first air mover 116a, a second air mover 116b, and an interconnect 118. The first support structure 106a can include the first heat source 108a (not shown) and the second support structure 106b can include the second heat source 108b (not shown). The heat pipe 110a can include the first side 112a and the opposite second side 112b. The first air mover 116a can be a fan or blower. The second air mover 116b can be a fan or blower.

The first support structure 106a can be over the first side 112a of the heat pipe 110a. The first air mover 116a can be over the first support structure 106a and more particularly over the first heat source 108a (not shown) on the first support structure 106a. The first air mover 116a can force air over and/or through heat exchangers 114a and 114b.

The second support structure 106b can be under the second side 112b of the heat pipe 110a. The second air mover 116b can be under the second support structure 106b and more particularly under the second heat source 108b (not shown) on the second support structure 106b. The second air mover 116b can force air over and/or through the heat exchangers 114c and 114d (not shown).

The interconnect 118 can couple the first support structure 106a to the second support structure 106b and allow for communication between components on the first support structure 106a and the second support structure 106b. More specifically, if the first support structure 106a is a first PCB or board and the first heat source 108a is a CPU on the first support structure 106a and the second support structure 106b is a second PCB or board and the second heat source 108b is a GPU on the second support structure 106b, the interconnect 118 can allow for communication between the CPU (the first heat source 108a) and the GPU (the second heat source 108b). In some examples, the interconnect 118 is a peripheral component interconnect express (PCIE) for data transfer between the first heat source 108a and the second heat source 108b. In other examples, the interconnect 118 is a different type of interconnect that allows data and/or power transfer between components on the first support structure 106a and the second support structure 106b. In yet other examples, the interconnect 118 may not be present if components on the first support structure 106a and the second support structure 106b do not need to be interconnected.

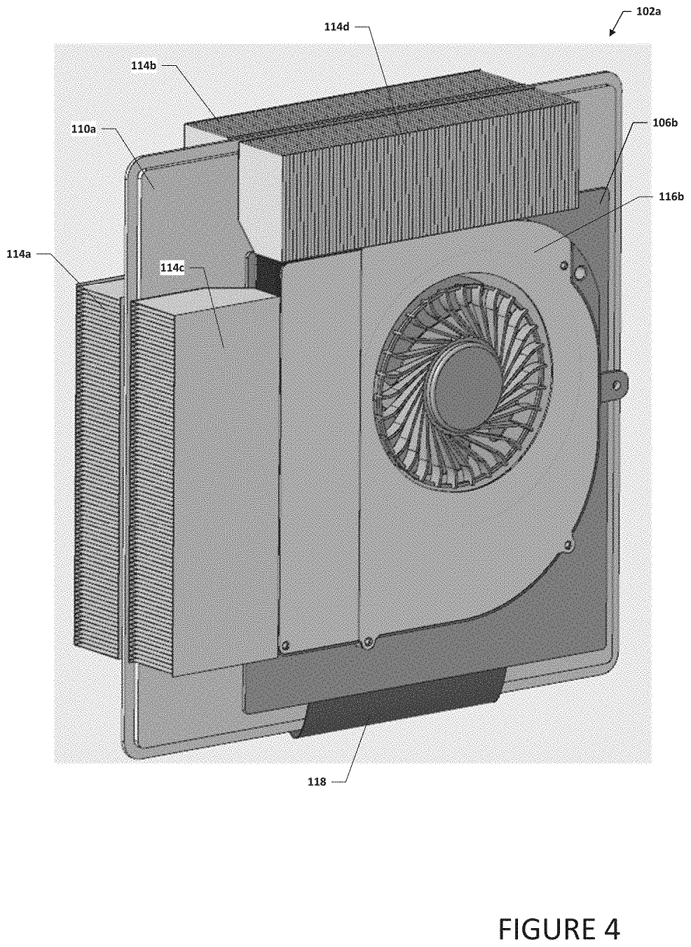

Turning to FIG. 4, FIG. 4 is a simplified block diagram of a portion of the electronic device 102a, in accordance with an embodiment of the present disclosure. FIG. 4 illustrates a bottom perspective view of the illustrated portion of the electronic device 102a. In an example, the electronic device 102a can include the first support structure 106a (not shown, illustrated in FIG. 3), the second support structure 106b, the heat pipe 110a, the heat exchangers 114a-114d, the first air mover 116a (not shown, illustrated in FIG. 3), the second air mover 116b, and the interconnect 118. The first support structure 106a (not shown, illustrated in FIG. 3) can include the first heat source 108a (not shown) and the second support structure 106b can include the second heat source 108b (not shown). The heat pipe 110a can include the first side 112a and the opposite second side 112b.

The first support structure 106a (not shown, illustrated in FIG. 3) can be over the first side 112a of the heat pipe 110a. The first air mover 116a (not shown, illustrated in FIG. 3) can be over the first support structure 106a (not shown, illustrated in FIG. 3) and more particularly under the first heat source 108a (not shown) on the first support structure 106a (not shown, illustrated in FIG. 3). The first air mover 116a (not shown, illustrated in FIG. 3) can force air over and/or through heat exchangers 114a and 114b.

The second support structure 106b can be under the second side 112b of the heat pipe 110a. The second air mover 116b can be under the second support structure 106b and more particularly over the second heat source 108b (not shown) on the second support structure 106b. The second air mover 116b can force air over and/or through the heat exchangers 114ca and 114d. The interconnect 118 can couple the first support structure 106a (not shown, illustrated in FIG. 3) to the second support structure 106b and allow for communication between components on the first support structure 106a (not shown, illustrated in FIG. 3) and the second support structure 106b.

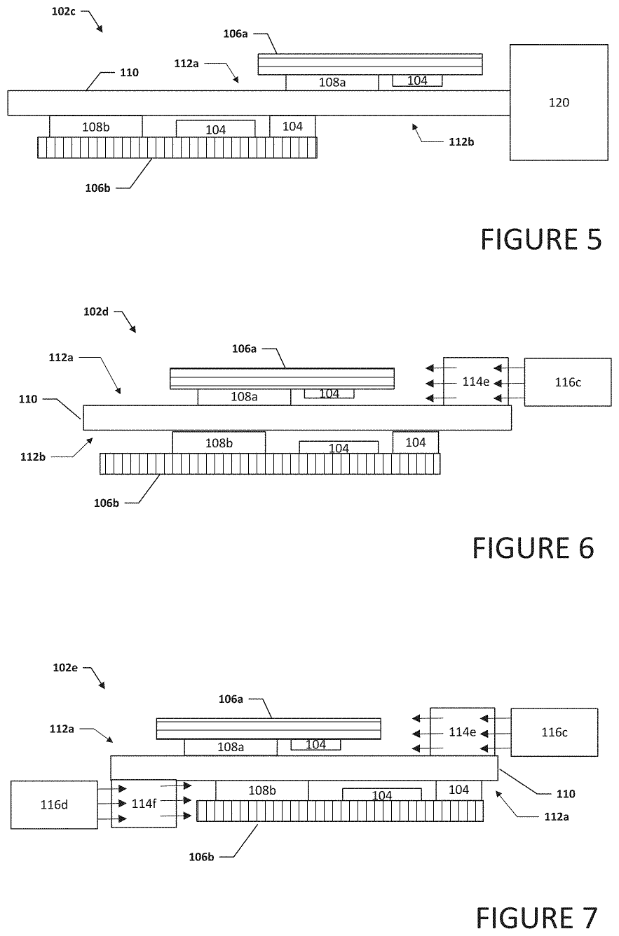

Turning to FIG. 5, FIG. 5 is a simplified block diagram of a portion of an electronic device 102c, in accordance with an embodiment of the present disclosure. In an example, the electronic device 102c can include one or more electronic components 104, the first support structure 106a, the second support structure 106b, the first heat source 108a, the second heat source 108b, the heat pipe 110, and a heat sink 120. The heat pipe 110 can include the first side 112a and the opposite second side 112b. The heat sink 120 can be an active heat sink or a passive heat sink.

The first heat source 108a can be coupled to the first support structure 106a and the first side 112a of the heat pipe 110. The second heat source 108b can be coupled to the second support structure 106b and the second side 112b of the heat pipe 110. On the first side 112a of the heat pipe 110, the heat pipe 110 can collect heat from the first heat source 108a. On the second side 112b of the heat pipe 110, the heat pipe 110 can collect heat from the second heat source 108b. The heat from the first heat source 108a and the second heat source 108b can be transferred to the heat sink 120 and away from the first heat source 108a and the second heat source 108b. The heat sink 120 can collect the heat from the heat pipe 110 and dissipate the heat to the environment around the electronic device 102c.

Turning to FIG. 6, FIG. 6 is a simplified block diagram of a portion of an electronic device 102d, in accordance with an embodiment of the present disclosure. In an example, the electronic device 102d can include one or more electronic components 104, the first support structure 106a, the second support structure 106b, the first heat source 108a, the second heat source 108b, the heat pipe 110, a heat exchanger 114e, and an air mover 116c. The heat pipe 110 can include the first side 112a and the opposite second side 112b. The heat exchanger 114e can include one or more fins. The air mover 116c can be a fan or blower.

The first heat source 108a can be coupled to the first support structure 106a and the first side 112a of the heat pipe 110. The second heat source 108b can be coupled to the second support structure 106b and the second side 112b of the heat pipe 110. On the first side 112a of the heat pipe 110, the heat pipe 110 can collect heat from the first heat source 108a. On the second side 112b of the heat pipe 110, the heat pipe 110 can collect heat from the second heat source 108b.

In an example, the heat exchanger 114e and the air mover 116c can be located on the first side 112a of the heat pipe 110. In another example, the heat exchanger 114e and the air mover 116c can be located on the second side 112b of the heat pipe 110. The heat from the first heat source 108a and the second heat source 108b can be transferred to the heat exchanger 114e and away from the first heat source 108a and the second heat source 108b. The air mover 116c can force air over and/or through the heat exchanger 114e and dissipate the heat to the environment around the electronic device 102d.

Turning to FIG. 7, FIG. 7 is a simplified block diagram of a portion of an electronic device 102e, in accordance with an embodiment of the present disclosure. In an example, the electronic device 102e can include one or more electronic components 104, the first support structure 106a, the second support structure 106b, the first heat source 108a, the second heat source 108b, the heat pipe 110, the heat exchanger 114e, a second heat exchanger 1141, the air mover 116c, and a second air mover 116d. The heat pipe 110 can include the first side 112a and the opposite second side 112b. The heat exchanger 114e can include one or more fins. The second heat exchanger 1141 can include one or more fins. The air mover 116c can be a fan or blower. The second air mover 116d can be a fan or blower.

The first heat source 108a can be coupled to the first support structure 106a and the first side 112a of the heat pipe 110. The second heat source 108b can be coupled to the second support structure 106b and the second side 112b of the heat pipe 110. On the first side 112a of the heat pipe 110, the heat pipe 110 can collect heat from the first heat source 108a. On the second side 112b of the heat pipe 110, the heat pipe 110 can collect heat from the second heat source 108b.

In an example, the heat exchanger 114e and the air mover 116c can be located on the first side 112a of the heat pipe 110 and the second heat exchanger 114f and the second air mover 116d can be located on the second side 112b of the heat pipe 110. The heat from the first heat source 108a and the second heat source 108b can be transferred to the heat exchanger 114e on the first side 112a of the heat pipe 110 and to the second heat exchanger 114f on the second side 112b of the heat pipe 110 and away from the first heat source 108a and the second heat source 108b. The air mover 116c can force air over and/or through the heat exchanger 114e and dissipate the heat to the environment around the electronic device 102e. The second air mover 116d can force air over and/or through the second heat exchanger 114f and dissipate the heat to the environment around the electronic device 102e.

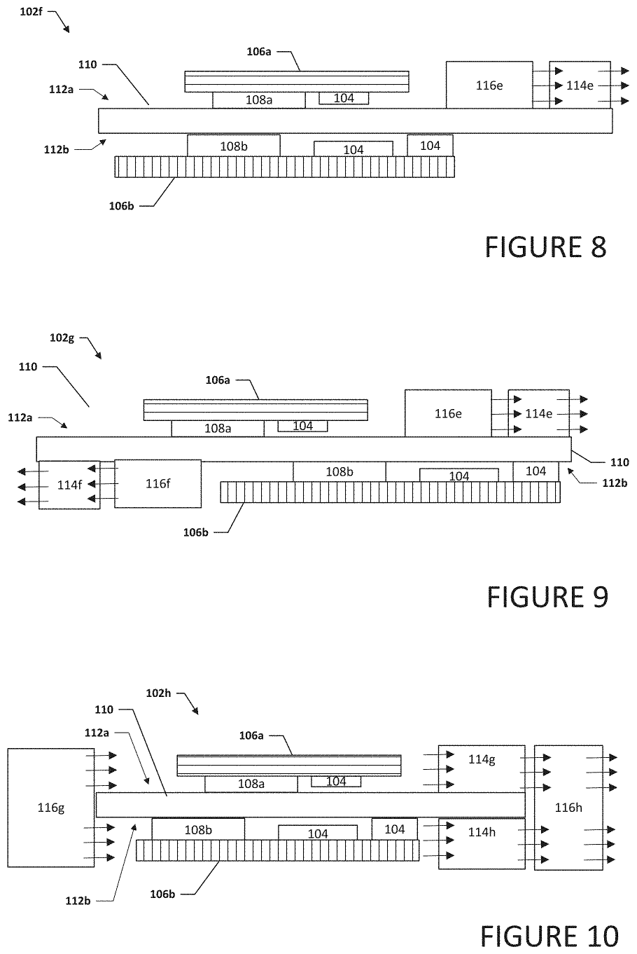

Turning to FIG. 8, FIG. 8 is a simplified block diagram of a portion of an electronic device 102f, in accordance with an embodiment of the present disclosure. In an example, the electronic device 102f can include one or more electronic components 104, the first support structure 106a, the second support structure 106b, the first heat source 108a, the second heat source 108b, the heat pipe 110, a heat exchanger 114e, and an air mover 116e. The heat pipe 110 can include the first side 112a and the opposite second side 112b. The heat exchanger 114e can include one or more fins. The air mover 116e can be a fan or blower.

The first heat source 108a can be coupled to the first support structure 106a and the first side 112a of the heat pipe 110. The second heat source 108b can be coupled to the second support structure 106b and the second side 112b of the heat pipe 110. On the first side 112a of the heat pipe 110, the heat pipe 110 can collect heat from the first heat source 108a. On the second side 112b of the heat pipe 110, the heat pipe 110 can collect heat from the second heat source 108b.

In an example, the heat exchanger 114e and the air mover 116e can be located on the first side 112a of the heat pipe 110. In another example, the heat exchanger 114e and the air mover 116e can be located on the second side 112b of the heat pipe 110. The heat from the first heat source 108a and the second heat source 108b can be transferred to the heat exchanger 114e and away from the first heat source 108a and the second heat source 108b. The air mover 116e can force air over and/or through the heat exchanger 114e and dissipate the heat to the environment around the electronic device 102f. As illustrated in FIG. 8, the direction of the airflow from the air mover 116e is away from the first heat source 108a as opposed to towards the first heat source 108a, as illustrated in FIG. 6.

Turning to FIG. 9, FIG. 9 is a simplified block diagram of a portion of an electronic device 102g, in accordance with an embodiment of the present disclosure. In an example, the electronic device 102g can include one or more electronic components 104, the first support structure 106a, the second support structure 106b, the first heat source 108a, the second heat source 108b, the heat pipe 110, the heat exchanger 114e, the second heat exchanger 114f, the air mover 116e, and a second air mover 116f. The heat pipe 110 can include the first side 112a and the opposite second side 112b. The heat exchanger 114e can include one or more fins. The second heat exchanger 114f can include one or more fins. The air mover 116e be a fan or blower. The second air mover 116f can be a fan or blower.

The first heat source 108a can be coupled to the first support structure 106a and the first side 112a of the heat pipe 110. The second heat source 108b can be coupled to the second support structure 106b and the second side 112b of the heat pipe 110. On the first side 112a of the heat pipe 110, the heat pipe 110 can collect heat from the first heat source 108a. On the second side 112b of the heat pipe 110, the heat pipe 110 can collect heat from the second heat source 108b.

In an example, the heat exchanger 114e and the air mover 116e can be located on the first side 112a of the heat pipe 110 and the second heat exchanger 114f and the second air mover 116f can be located on the second side 112b of the heat pipe 110. The heat from the first heat source 108a and the second heat source 108b can be transferred to the heat exchanger 114e on the first side 112a of the heat pipe 110 and to the second heat exchanger 114f on the second side 112b of the heat pipe 110 and away from the first heat source 108a and the second heat source 108b. The air mover 116e can force air over and/or through the heat exchanger 114e and dissipate the heat to the environment around the electronic device 102e. As illustrated in FIG. 9, the direction of the airflow from the air mover 116e is away from the first heat source 108a as opposed to towards the first heat source 108a, as illustrated in FIG. 7. The second air mover 116f can force air over and/or through the second heat exchanger 114f and dissipate the heat to the environment around the electronic device 102g. As illustrated in FIG. 9, the direction of the airflow from the second air mover 116f is away from the second heat source 108a as opposed to towards the first heat source 108a, as illustrated in FIG. 7.

Turning to FIG. 10, FIG. 110 is a simplified block diagram of a portion of an electronic device 102h, in accordance with an embodiment of the present disclosure. In an example, the electronic device 102h can include one or more electronic components 104, the first support structure 106a, the second support structure 106b, the first heat source 108a, the second heat source 108b, the heat pipe 110, a first side heat exchanger 114g, a second side heat exchanger 114h, and one or more air movers 116. For example, as illustrated in FIG. 10, electronic device 102h includes an air mover 116g and an air mover 116h. The heat pipe 110 can include the first side 112a and the opposite second side 112b. The heat exchanger 114e can include one or more fins. The second heat exchanger 114f can include one or more fins. The air mover 116g be a fan or blower. The air mover 116h can be a fan or blower.

The first heat source 108a can be coupled to the first support structure 106a and the first side 112a of the heat pipe 110. The second heat source 108b can be coupled to the second support structure 106b and the second side 112b of the heat pipe 110. On the first side 112a of the heat pipe 110, the heat pipe 110 can collect heat from the first heat source 108a. On the second side 112b of the heat pipe 110, the heat pipe 110 can collect heat from the second heat source 108b.

In an example, the first side heat exchanger 114g can be located on the first side 112a of the heat pipe 110 and the second side heat exchanger 114h can be located on the second side 112b of the heat pipe 110. The heat from the first heat source 108a and the second heat source 108b can be transferred to the first side heat exchanger 114g on the first side 112a of the heat pipe 110 and to the second side heat exchanger 114h on the second side 112b of the heat pipe 110 and away from the first heat source 108a and the second heat source 108b. The air mover 116g can force or push air over and/or through the heat exchanger 114e. The air mover 116h can draw air over and/or through the heat exchanger 114e and dissipate the heat to the environment around the electronic device 102e. As illustrated in FIG. 10, the direction of the airflow from the air mover 116g is towards the first heat source 108a and the second heat source 108b and the direction of the airflow from the air mover 116h is away from the first heat source 108a and the second heat source 108b.

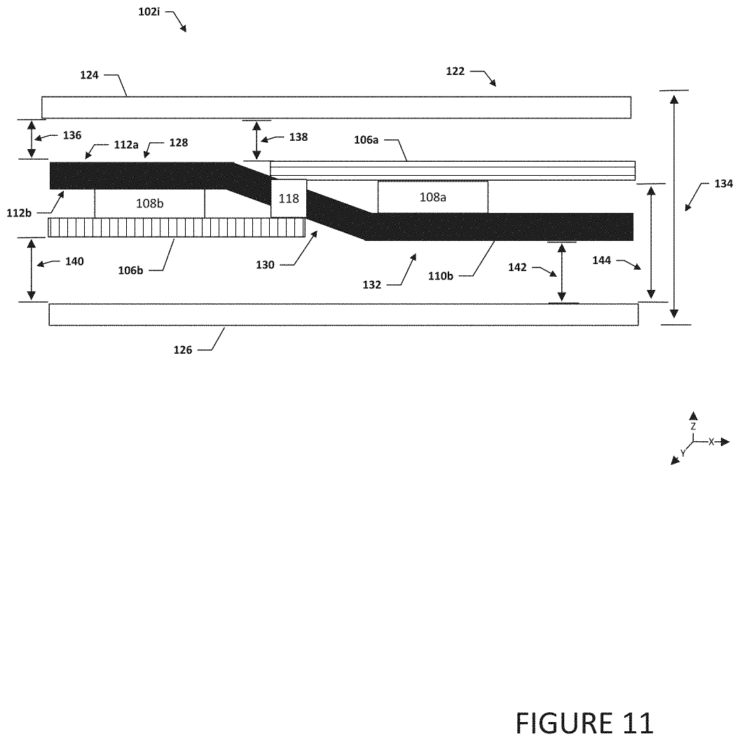

Turning to FIG. 11, FIG. 11 is a simplified block diagram of a portion of an electronic device 102i, in accordance with an embodiment of the present disclosure. In an example, the electronic device 102i can include the first support structure 106a, the second support structure 106b, the first heat source 108a, the second heat source 108b, a heat pipe 110b, the interconnect 118, and a chassis 122. The chassis 122 can include a first side 124 (e.g., keyboard side) and a second side 126 (e.g., bottom side).

The heat pipe 110b can include the first side 112a and the opposite second side 112b. The heat pipe 110b can also include a first portion 128, a middle portion 130, and a second portion 132. The middle portion 130 is between the first portion 128 and the second portion 132. In some examples, the middle portion 130 has a bend or is angled such that the first portion 128 is on about the same plane as the first support structure 106a and/or the second portion 132 is on about the same plane as the second support structure 106b.

The first heat source 108a can be coupled to the first support structure 106a and the first side 112a of the heat pipe 110b. The second heat source 108b can be coupled to the second support structure 106b and the second side 112b of the heat pipe 110b. The heat from the first heat source 108a and the second heat source 108b can be transferred to the heat pipe 110b and away from the first heat source 108a and the second heat source 108b.

In a specific example, where a total distance 134 between the first side 124 (e.g., keyboard side) and the second side 126 (e.g., bottom side) of the chassis is about seventeen (17) mm. A first side to first portion of heat pipe distance 136 (the distance between the first side 124 of the chassis 122 to the first portion 128 of the heat pipe 110b) can be about 4.5 mm to about 5.5 mm and ranges therein (e.g., between about 4.7 and about 5.3 millimeters, between about 4.9 and about 5.2 millimeters, etc.), depending on design choice and design constraints. In a specific example, the first portion of heat pipe distance 136 is about five (5) mm. A first side to first support structure distance 138 (the distance between the first side 124 of the chassis 122 to the first support structure 106a) can be about 4.5 mm to about 5.5 mm and ranges therein (e.g., between about 4 and about 5 millimeters, between about 4.8 and about 5.2 millimeters, etc.), depending on design choice and design constraints. In a specific example, the first side to first support structure distance 138 is about 5.3 mm. A second side to second support structure distance 140 (the distance between the second side 126 of the chassis 122 to the second support structure 106b) can be about 3.5 mm to about 4.5 mm and ranges therein (e.g., between about 3.5 and about 4 millimeters, between about 3.8 and about 4.2 millimeters, etc.), depending on design choice and design constraints. In a specific example, the second support structure distance 140 can be about four (4) mm. A second side to second portion of heat pipe distance 142 (the distance between the second side 126 of the chassis 122 to the second portion 132 of the heat pipe 110b) can be about 3.5 mm to about 4.5 mm and ranges therein (e.g., between about 3.8 and about 4.2 millimeters, between about 3.9 and about 4.4 millimeters, etc.), depending on design choice and design constraints. In a specific example, the second side to second portion of heat pipe distance 142 can be about four (4) mm. A second side to first support structure distance 144 (the distance between the second side 126 of the chassis 122 to the first support structure 106a) can be about 8.5 mm to about 9.5 mm and ranges therein (e.g., between about 8.6 and about 9.2 millimeters, between about 8.9 and about 9.34 millimeters, etc.), depending on design choice and design constraints. In a specific example, the second side to first support structure distance 144 can be about nine (9) mm. As would be obvious to one skilled in the art, the above example distances could change depending on design constraints and design choice. For example, if the total distance 134 was greater than seventeen (17) mm, then one or more of the other examples distances could also be increased.

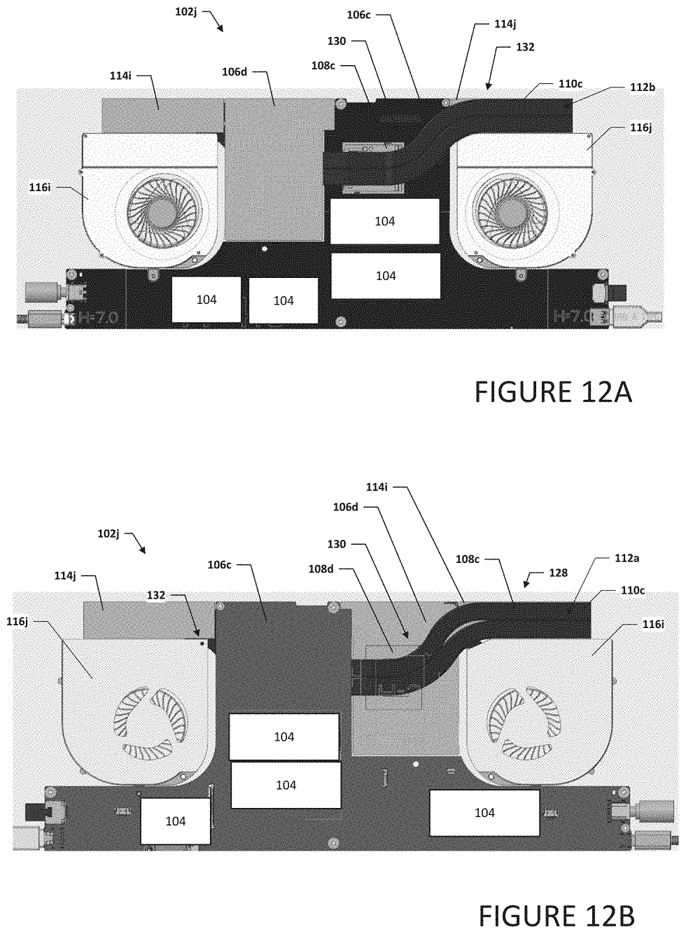

Turning to FIGS. 12A and 12B, FIGS. 12A and 12B are a simplified block diagrams of a portion of an electronic device 102j, in accordance with an embodiment of the present disclosure. FIG. 12A is a view from one side of the electronic device (e.g., the first side) and FIG. 12B is a view from the opposite second side of the electronic device (e.g., the second side). In an example, the electronic device 102j can include one or more electronic components 104, a first electronic device support structure 106c, a second electronic device support structure 106d, a first electronic device heat source 108c, a second electronic device heat source 108d, a heat pipe 110c, a first side heat exchanger 114i, a second side heat exchanger 114j, a first electronic device air mover 116i, and a second electronic device air mover 116j.

The heat pipe 110c can include the first side 112a (illustrated in FIG. 12B) and the opposite second side 112b (illustrated in FIG. 12A). The heat pipe 110c can also include the first portion 128 (illustrated in FIG. 12B), the middle portion 130, and the second portion 132. The middle portion 130 is between the first portion 128 and the second portion 132. In some examples, the middle portion 130 has a bend or is angled such that the first portion 128 is on about the same plane as the first electronic device support structure 106c and/or the second portion 132 is on about the same plane as the second electronic device support structure 106d.

The first electronic device heat source 108c can be coupled to the first electronic device support structure 106c and the first side 112a of the heat pipe 110c. The second electronic device heat source 108d can be coupled to the second support structure 106b and the second side 112b of the heat pipe 110b. The first side heat exchanger 114i can be located on the second side 112b of the heat pipe 110c and the second side heat exchanger 114j can be located on the first side 112a of the heat pipe 110c. The heat from the first electronic device heat source 108c and the second electronic device heat source 108d can be transferred to the heat pipe 110c and away from the first heat source 108a and the second heat source 108b.

The heat in the heat pipe 110c (from the first heat source 108a and the second heat source 108b) can be transferred to the first side heat exchanger 114i on the second side 112b of the heat pipe 110 and to the second side heat exchanger 114j on the first side 112a of the heat pipe 110. The first electronic device air mover 116i can force or push air over and/or through the first side heat exchanger 114i to help dissipate the collected heat to the environment around the electronic device 102j. The second electronic device air mover 116j can force or push air over and/or through the second side heat exchanger 114j to help dissipate the collected heat to the environment around the electronic device 102j.

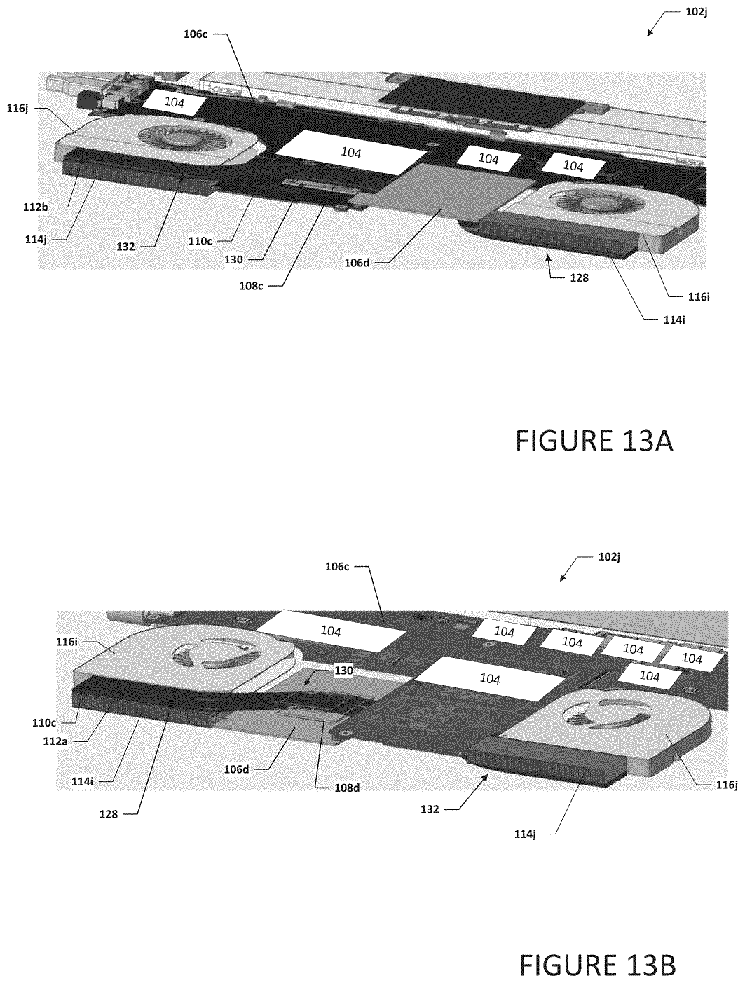

Turning to FIGS. 13A and 13B, FIGS. 13A and 13B are a simplified block diagrams of a portion of an electronic device 102j, in accordance with an embodiment of the present disclosure. FIG. 13A is a perspective view from one side of the electronic device (e.g., the first side) and FIG. 13B is a perspective view from the opposite second side of the electronic device (e.g., the second side). In an example, the electronic device 102j can include one or more electronic components 104, the first electronic device support structure 106c, the second electronic device support structure 106d, the first electronic device heat source 108c, the second electronic device heat source 108d, the heat pipe 110c, the first side heat exchanger 114i, the second side heat exchanger 114j, the first electronic device air mover 116i, and the second electronic device air mover 116j.

The heat pipe 110c can include the first side 112a (illustrated in FIG. 13B) and the opposite second side 112b (illustrated in FIG. 13A). The heat pipe 110c can also include the first portion 128, the middle portion 130, and the second portion 132. The middle portion 130 is between the first portion 128 and the second portion 132. In some examples, the middle portion 130 has a bend or is angled such that the first portion 128 is on about the same plane as the first electronic device support structure 106c and the second portion 132 is on about the same plane as the second electronic device support structure 106d.

The first electronic device heat source 108c can be coupled to the first electronic device support structure 106c and the first side 112a of the heat pipe 110c. The second electronic device heat source 108d can be coupled to the second support structure 106b and the second side 112b of the heat pipe 110b. The first side heat exchanger 114i can be located on the second side 112b of the heat pipe 110c and the second side heat exchanger 114j can be located on the first side 112i of the heat pipe 110c. The heat from the first electronic device heat source 108c and the second electronic device heat source 108d can be transferred to the heat pipe 110c and away from the first heat source 108a and the second heat source 108b.

The heat in the heat pipe 110c (from the first heat source 108a and the second heat source 108b) can be transferred to the first side heat exchanger 114i on the second side 112b of the heat pipe 110 and to the second side heat exchanger 114j on the first side 112a of the heat pipe 110. The first electronic device air mover 116i can force or push air over and/or through the first side heat exchanger 114i to help dissipate the collected heat to the environment around the electronic device 102j. The second electronic device air mover 116j can force or push air over and/or through the second side heat exchanger 114j to help dissipate the collected heat to the environment around the electronic device 102j.

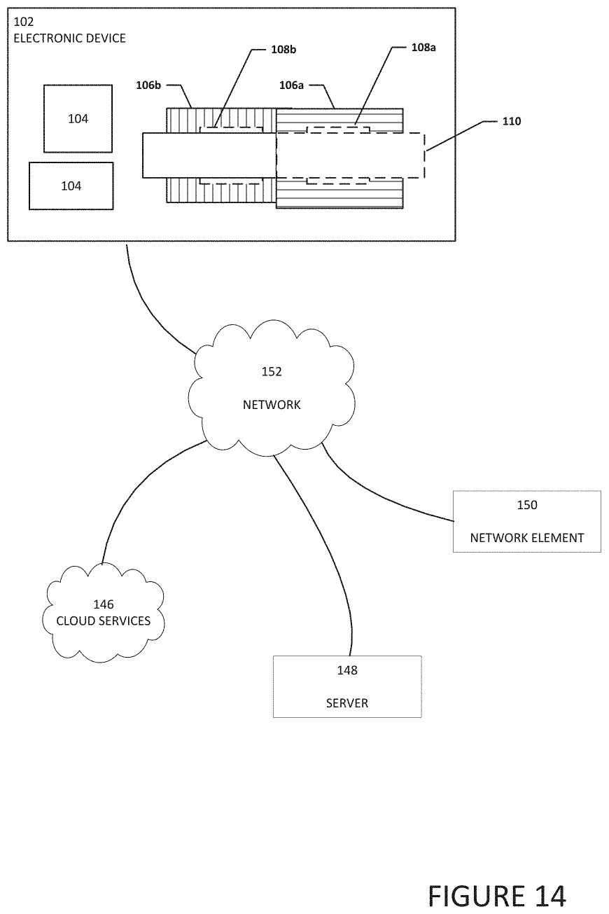

Turning to FIG. 14, FIG. 14 is a simplified block diagram of an electronic device 102 configured with a heat pipe with a first heat source on a first side and a second heat source on an opposite second side, in accordance with an embodiment of the present disclosure. In an example, the electronic device 102 can include the one or more electronic components 104, the first support structure 106a, the second support structure 106b, and the heat pipe 110. The first support structure 106a can include the first heat source 108a and the second support structure 106b can include the second heat source 108b. In some examples, the heat pipe 110 is a vapor chamber. The heat pipe 110 can include the first side 112a (referenced in FIG. 1B) and the second side 112b (referenced in FIG. 1B). The first side 112a of the heat pipe 110 is opposite the second side 112b of the heat pipe 110. The first support structure 104a, and more particularly the first heat source 108a can be over the first side 112a of the heat pipe 110. The second support structure 104b, and more particularly the second heat source 108b can be under the second side 112b of the heat pipe 110. Note that the terms “over” and “under” are relative terms depending on the orientation of the electronic device and heat pipe. More specifically, in a different orientation, the first support structure 104a, and more particularly the first heat source 108a can be under the first side 112a of the heat pipe 110 and the second support structure 104b, and more particularly the second heat source 108b can be over the second side 112b of the heat pipe 110.

Each of the first heat source 108a and the second heat source 108b may be a heat generating device (e.g., processor, logic unit, field programmable gate array (FPGA), chip set, integrated circuit (IC), a graphics processor, graphics card, battery, memory, or some other type of heat generating device). The first support structure 104a and the second support structure 104b can each be a substrate such as a non-semiconductor substrate or a semiconductor substrate and more particularly, a PCB. In one implementation, the non-semiconductor substrate may be silicon dioxide, an inter-layer dielectric composed of silicon dioxide, silicon nitride, titanium oxide and other transition metal oxides. Although a few examples of materials from which the non-semiconducting substrate may be formed are described here, any material that may serve as a foundation upon which a non-semiconductor device may be built falls within the spirit and scope of the embodiments disclosed herein.

In another implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. In other examples, the substrate may be a flexible substrate including 2D materials such as graphene and molybdenum disulphide, organic materials such as pentacene, transparent oxides such as indium gallium zinc oxide poly/amorphous (low temperature of dep) III-V semiconductors and germanium/silicon, and other non-silicon flexible substrates. Although a few examples of materials from which the substrate may be formed are described here, any material that may serve as a foundation upon which a semiconductor device may be built falls within the spirit and scope of the embodiments disclosed herein.

The electronic device 102 (and the electronic devices 102a-102j) may be in communication with cloud services 146, one or more servers 148, and/or one or more network elements 150 using a network 152. In some examples, the electronic device 102 (and the electronic devices 102a-102j) may be standalone devices and not connected to the network 152 or another device

Elements of FIG. 14 may be coupled to one another through one or more interfaces employing any suitable connections (wired or wireless), which provide viable pathways for network (e.g., the network 152, etc.) communications. Additionally, any one or more of these elements of FIG. 10 may be combined or removed from the architecture based on particular configuration needs. The network 152 may include a configuration capable of transmission control protocol/Internet protocol (TCP/IP) communications for the transmission or reception of packets in a network. The electronic devices 102 and 102a-102j) may also operate in conjunction with a user datagram protocol/IP (UDP/IP) or any other suitable protocol where appropriate and based on particular needs.

Turning to the infrastructure of FIG. 10, the network 152 represents a series of points or nodes of interconnected communication paths for receiving and transmitting packets of information. The network 152 offers a communicative interface between nodes, and may be configured as any local area network (LAN), virtual local area network (VLAN), wide area network (WAN), wireless local area network (WLAN), metropolitan area network (MAN), Intranet, Extranet, virtual private network (VPN), and any other appropriate architecture or system that facilitates communications in a network environment, or any suitable combination thereof, including wired and/or wireless communication.

In the network 152, network traffic, which is inclusive of packets, frames, signals, data, etc., can be sent and received according to any suitable communication messaging protocols. Suitable communication messaging protocols can include a multi-layered scheme such as Open Systems Interconnection (OSI) model, or any derivations or variants thereof (e.g., Transmission Control Protocol/Internet Protocol (TCP/IP), user datagram protocol/IP (UDP/IP)). Messages through the network could be made in accordance with various network protocols, (e.g., Ethernet, Infiniband, OmniPath, etc.). Additionally, radio signal communications over a cellular network may also be provided. Suitable interfaces and infrastructure may be provided to enable communication with the cellular network.

The term “packet” as used herein, refers to a unit of data that can be routed between a source node and a destination node on a packet switched network. A packet includes a source network address and a destination network address. These network addresses can be Internet Protocol (IP) addresses in a TCP/IP messaging protocol. The term “data” as used herein, refers to any type of binary, numeric, voice, video, textual, or script data, or any type of source or object code, or any other suitable information in any appropriate format that may be communicated from one point to another in electronic devices and/or networks.

Although the present disclosure has been described in detail with reference to particular arrangements and configurations, these example configurations and arrangements may be changed significantly without departing from the scope of the present disclosure. Moreover, certain components may be combined, separated, eliminated, or added based on particular needs and implementations. Additionally, although the electronic devices 102 and 102a-102e have been illustrated with reference to particular elements and operations, these elements and operations may be replaced by any suitable architecture, protocols, and/or processes that achieve the intended functionality of the electronic devices 102 and 102a-102e.

Numerous other changes, substitutions, variations, alterations, and modifications may be ascertained to one skilled in the art and it is intended that the present disclosure encompass all such changes, substitutions, variations, alterations, and modifications as falling within the scope of the appended claims. In order to assist the United States Patent and Trademark Office (USPTO) and, additionally, any readers of any patent issued on this application in interpreting the claims appended hereto, Applicant wishes to note that the Applicant: (a) does not intend any of the appended claims to invoke paragraph six (6) of 35 U.S.C. section 112 as it exists on the date of the filing hereof unless the words “means for” or “step for” are specifically used in the particular claims; and (b) does not intend, by any statement in the specification, to limit this disclosure in any way that is not otherwise reflected in the appended claims.

### OTHER NOTES AND EXAMPLES

In Example A1, an electronic device can include a first heat source on a first support structure, a second heat source on a second support structure, and a heat pipe that has a first side and an opposite second side, where the first heat source is coupled to the first side of the heat pipe and the second heat source is coupled to the second side of the heat pipe.

In Example A2, the subject matter of Example A1 can optionally include where the heat pipe is a vapor chamber.

In Example A3, the subject matter of Example A1 can optionally include where the first heat source is a computer processing unit and the second heat source is a graphics processing unit.

In Example A4, the subject matter of Example A1 can optionally include a first heat exchanger, a first air mover, a second heat exchanger, and a second air mover.

In Example A5, the subject matter of Example A4 can optionally include where the first side of the heat pipe is in contact with the second heat exchanger and the second side of the heat pipe is in contact with the first heat exchanger.

In Example A6, the subject matter of Example A5 can optionally include where the first air mover is a fan and the first heat exchanger is a plurality of fins.

In Example A7, the subject matter of Example A1 can optionally include where the heat pipe includes a bend or is angled such that the first support structure and the second side of the heat pipe are on about a same plane.

In Example A8, the subject matter of any of Examples A1-A2 can optionally include where the first heat source is a computer processing unit and the second heat source is a graphics processing unit.

In Example A9, the subject matter of any of Examples A1-A3 can optionally include a first heat exchanger, a first air mover, a second heat exchanger, and a second air mover.

In Example A10, the subject matter of any of Examples A1-A4 can optionally include where the first side of the heat pipe is in contact with the second heat exchanger and the second side of the heat pipe is in contact with the first heat exchanger.

In Example A11, the subject matter of any of Examples A1-A5 can optionally include where the first air mover is a fan and the first heat exchanger is a plurality of fins.

In Example A12, the subject matter of any of Examples A1-A6 can optionally include where the heat pipe includes a bend or is angled such that the first support structure and the second side of the heat pipe are on about a same plane.

Example AA1 is a device including a first support structure that includes a first heat source, a second support structure that includes a second heat source, and a heat pipe between the first heat source and the second heat source, where the first heat source is coupled to a first side of the heat pipe and the second heat source is coupled to an opposite second side of the heat pipe.

In Example AA2, the subject matter of Example AA1 can optionally include where the heat pipe includes a first portion on a first end of the heat pipe, a second portion on a second opposite end of the heat pipe, and a middle portion between the first portion and the second portion, where the middle portion includes a bend or angle in the heat pipe.

In Example AA3, the subject matter of Example AA2 can optionally include where the bend or angle allows the first support structure and the second side of the heat pipe to be on about a same plane.

In Example AA4, the subject matter of Example AA3 can optionally include a first heat exchanger coupled to the first side of the first portion of the heat pipe and a second heat exchanger coupled to the second side of the second portion of the heat pipe.

In Example AA5, the subject matter of Example AA4 can optionally include a first air mover located near the first portion of the heat pipe, where the first air mover forces air through the first heat exchanger and a second air mover located near the second portion of the heat pipe, where the second air mover forces air through the second heat exchanger.

In Example AA6, the subject matter of Example AA1 can optionally include where the first support structure is a computer processing unit printed circuit board, the first heat source is a computer processing unit, the second support structure is a graphics processing unit printed circuit board, and the second heat source is a graphics processing unit.

In Example AA7, the subject matter of Example AA1 can optionally include where the heat pipe is a vapor chamber.

In Example AA8, the subject matter of any of Examples AA1-AA2 can optionally include where the bend or angle allows the first support structure and the second side of the heat pipe to be on about a same plane.

In Example AA9, the subject matter of any of Examples AA1-AA3 can optionally include where a first heat exchanger coupled to the first side of the first portion of the heat pipe and a second heat exchanger coupled to the second side of the second portion of the heat pipe.

In Example AA10, the subject matter of any of Examples AA1-AA4 can optionally include a first air mover located near the first portion of the heat pipe, where the first air mover forces air through the first heat exchanger and a second air mover located near the second portion of the heat pipe, where the second air mover forces air through the second heat exchanger.

In Example AA11, the subject matter of any of Examples AA1-AA5 can optionally include where the first support structure is a computer processing unit printed circuit board, the first heat source is a computer processing unit, the second support structure is a graphics processing unit printed circuit board, and the second heat source is a graphics processing unit.

In Example AA12, the subject matter of any of Examples AA1-AA6 can optionally include where the heat pipe is a vapor chamber.

Example M1 is a method including coupling a first heat source on a first substrate to a first side of a heat pipe and coupling a second heat source on a second substrate to a second side of the heat pipe, where the second side of the heat pipe is opposite the first side of the heat pipe.

In Example M2, the subject matter of Example M1 can optionally include where the heat pipe is a vapor chamber.

In Example M3, the subject matter of Example M1 can optionally include where the first heat source is a computer processing unit and the second heat source is a graphics processing unit.

In Example M4, the subject matter of Example M1 can optionally include coupling a first heat exchanger to the first side of the heat pipe and coupling a second heat exchanger to the second side of the heat pipe.

In Example M5, the subject matter of Example M4 can optionally include forcing air through the first heat exchanger using a first air mover and forcing air through the second heat exchanger using a second air mover.

In Example, M6, the subject matter of Example M1 can optionally include where the first substrate and the second side of the heat pipe are on about a same plane.

In Example M3, the subject matter of any of the Examples M1-M2 can optionally include where the first heat source is a computer processing unit and the second heat source is a graphics processing unit.

In Example M4, the subject matter of any of the Examples M1-M3 can optionally include coupling a first heat exchanger to the first side of the heat pipe and coupling a second heat exchanger to the second side of the heat pipe.

In Example M5, the subject matter of any of the Examples M1-M4 can optionally include where forcing air through the first heat exchanger using a first air mover and forcing air through the second heat exchanger using a second air mover.

In Example, M6, the subject matter of any of the Examples M1-M5 can optionally include where the first substrate and the second side of the heat pipe are on about a same plane.

What is claimed is:

1. An electronic device comprising:
a first heat source on a first support structure;
a second heat source on a second support structure; and
a heat pipe that has a first side and an opposite second side, wherein the first heat source is coupled to the first side of the heat pipe and the second heat source is coupled to the second side of the heat pipe.

2. The electronic device of claim 1, wherein the heat pipe is a vapor chamber.

3. The electronic device of claim 1, wherein the first heat source is a computer processing unit and the second heat source is a graphics processing unit.

4. The electronic device of claim 1, further comprising:
a first heat exchanger;
a first air mover;
a second heat exchanger; and
a second air mover.

5. The electronic device of claim 4, wherein the first side of the heat pipe is in contact with the second heat exchanger and the second side of the heat pipe is in contact with the first heat exchanger.

6. The electronic device of claim 5, wherein the first air mover is a fan and the first heat exchanger is a plurality of fins.

7. The electronic device of claim 1, wherein the heat pipe includes a bend or is angled such that the first support structure and the second side of the heat pipe are on about a same plane.

8. A device comprising:
a first support structure that includes a first heat source;
a second support structure that includes a second heat source; and
a heat pipe between the first heat source and the second heat source, wherein the first heat source is coupled to a first side of the heat pipe and the second heat source is coupled to an opposite second side of the heat pipe.

9. The device of claim 8, wherein the heat pipe includes a first portion on a first end of the heat pipe, a second portion on a second opposite end of the heat pipe, and a middle portion between the first portion and the second portion, wherein the middle portion includes a bend or angle in the heat pipe.

10. The device of claim 9, wherein the bend or angle allows the first support structure and the second side of the heat pipe to be on about a same plane.

11. The device of claim 10 further comprising:
a first heat exchanger coupled to the first side of the first portion of the heat pipe; and
a second heat exchanger coupled to the second side of the second portion of the heat pipe.

12. The device of claim 11, further comprising:
a first air mover located near the first portion of the heat pipe, wherein the first air mover forces air through the first heat exchanger; and
a second air mover located near the second portion of the heat pipe, wherein the second air mover forces air through the second heat exchanger.

13. The device of claim 8, wherein the first support structure is a computer processing unit printed circuit board, the first heat source is a computer processing unit, the second support structure is a graphics processing unit printed circuit board, and the second heat source is a graphics processing unit.

14. The device of claim 8, wherein the heat pipe is a vapor chamber.

15. A method comprising:
coupling a first heat source on a first substrate to a first side of a heat pipe; and
coupling a second heat source on a second substrate to a second side of the heat pipe, wherein the second side of the heat pipe is opposite the first side of the heat pipe.

16. The method of claim 15, wherein the heat pipe is a vapor chamber.

17. The method of claim 15, wherein the first heat source is a computer processing unit and the second heat source is a graphics processing unit.

18. The method of claim 15, further comprising:
coupling a first heat exchanger to the first side of the heat pipe; and
coupling a second heat exchanger to the second side of the heat pipe.

19. The method of claim 18, further comprising:
forcing air through the first heat exchanger using a first air mover; and
forcing air through the second heat exchanger using a second air mover.

20. The method of claim 15, wherein the first substrate and the second side of the heat pipe are on about a same plane.
